(19) United States
(12) Patent Application Publication
(10) Pub. No.: US 2017/0098529 A1
(43) Pub. Date: Apr. 6, 2017

(54) RADIO FREQUENCY IDENTIFICATION IN-METAL INSTALLATION AND ISOLATION FOR SPUTTERING TARGET

(71) Applicant: Tosoh SMD, Inc., Grove City, OH (US)

(72) Inventors: Justin K. Reed, Reynoldsburg, OH (US); Erich Theado, Columbus, OH (US); Kenneth Fielder, Circleville, OH (US); Gerald Stevens, Columbus, OH (US); Ronald Alan Dilley, Lancaster, OH (US); John Hardy Burley, Grove City, OH (US)

(21) Appl. No.: 15/314,554

(22) PCT Filed: May 13, 2015
(86) PCT No.: PCT/US2015/030561

§ 371 Date: Nov. 29, 2016

Related U.S. Application Data
(60) Provisional application No. 62/004,939, filed on May 30, 2014.
(60) Provisional application No. 62/092,419, filed on Dec. 16, 2014.

(51) Int. Cl. H01J 37/32; C23C 14/34; G06K 19/077; H01J 37/34

(52) U.S. Cl. CPC H01J 37/32935; H01J 37/3417; C23C 14/3407; G06K 19/07749

(57) ABSTRACT

A RFID tag containment combination for a sputter target/backing plate assembly. A bore is provided in either the target or the backing plate and is adapted for snug receipt of a plug therein. The plug comprises a recessed portion thereof configured to carry the RFID tag therein.

### CROSS REFERENCE TO RELATED APPLICATIONS

This application claims the priority benefit of U.S. Provisional Patent Application Ser. No. 62/004,939 filed May 30, 2014 and U.S. Provisional Patent Application Ser. No. 62/092,419 filed Dec. 16, 2014.

### FIELD OF INVENTION

The invention pertains to a sputter target/backing plate assembly that is provided with an RFID tag embedded in either the target or backing plate by a plug and corresponding bore configured to accurately position the chip for read/write communication with an RFID reader.

### BACKGROUND OF THE INVENTION

Radio frequency identification (RFID) technology is used in a variety of environments to provide wireless automated identification and functioning of a variety of goods. RFID systems typically include a transponder referred to as a “tag” which is mounted to the good or device to be identified and a “tag” reader that communicates with the transponder.

In many cases, the tag or transponder responds to a wireless interrogation signal that is transmitted to it by the RF tag reader via an antenna. The response is forwarded to a computer to translate the response into a useable format.

Sputter coating or physical deposition methods are widely used for the deposition of thin layers of materials on a variety of substrates. Basically, this process requires gas ion bombardment of a sputter target having a face formed of a material that is to be deposited as a thin film or layer on a substrate. Ion bombardment of the target not only causes atoms or molecules of the target material to be sputtered, but imparts considerable thermal energy to the target. This heat is dissipated by use of a cooling fluid typically circulated beneath or around a heat conducting backing plate that is positioned in heat exchange relation with the target.

The cathode assembly is subjected to an evacuated chamber on the deposition face and cooling water on the opposite face. Each surface needs to have an O-ring that is compressed with a ceramic ring to complete the seal. Any added feature to the cathode assembly must not degrade these seals as they are essential to their performance.

The target forms a part of a cathode assembly which together with an anode is placed in an evacuated chamber that contains an inert gas, preferably argon. A high voltage electrical field is applied across the cathode and anode. The inert gas is ionized by collision with the electron ejected from the cathode. Positively charged gas ions are attracted to the cathode and, upon impingement of the target surface, dislodge the target material. The dislodged target materials traverse the evacuated enclosure and deposit as a thin film on the desired substrate that is normally located proximate the anode.

In typical target cathode assemblies, the target is attached to a nonmagnetic backing plate. The backing plate is normally water-cooled to carry away the heat generated by the ion bombardment of the target. Magnets are typically arranged beneath the backing plate in well-known disposition in order to form a magnetic field in the form of a loop or tunnel extending around the exposed face of the target.

In the past, RFID tags have been adhered utilizing an epoxy to encapsulate the tag or chip proximate a flange portion of the target. Due to the manual processes used to make these epoxy structures, the distance of the chips from side walls was random, without uniform optimization from assembly to assembly. Further, epoxy recipes varied and often incorporated bubbles, adversely affecting receipt and transmission of the RF signals.

### SUMMARY OF THE INVENTION

In one exemplary embodiment, a sputter target/backing plate assembly is provided of the type wherein an RFID tag is embedded in the assembly. A containment combination is therefore presented which includes a bore formed in one of the backing plate or sputter target and a plug adapted for snug insertion into the bore. The plug comprises an outer face and a recessed portion. A solid section of the plug is provided that borders at least a portion of the recessed plug portion. The recessed portion of the plug is configured to firmly receive an RFID tag therein. An O-ring seals the plug when it is received in the bore.

In other exemplary embodiments, a bore in the backing plate or target is required to allow the O-rings to compress and form the evacuated seal and the water seal. An RFID tag that is simply attached on one of the surfaces will not allow for proper seals to form.

In other exemplary embodiments, the bore is disposed along a peripheral surface portion of the backing plate. In some cases, this surface of the backing plate is provided along the back side or water side of the backing plate adapted for impingement of cooling water thereon.

In other embodiments, the plug and O-ring allows for small displacements. In some cases, this could be essential to forming an effective seal for either the evacuated seal or the water seal.

In yet other embodiments, the outer face of the plug and the peripheral portion of the backing plate, together, define a planar surface.

In yet other embodiments, the plug comprises a peripheral groove therein. Another groove is formed along a surface of the bore. The peripheral groove of the plug and this second groove provided in the bore define a mating interfacial surface upon snug insertion of the plug into the bore.

The recess portion of the plug may comprise a tool installation concavity adapted for insertion of a small tool or the like therein to facilitate placement and removal of the chip in the recess. Further, in certain embodiments, the recess portion of the plug is defined by a parallelogram, each side of which is connected to another side at a radiused section. Further, in certain embodiments, each of the sides of the recess is equally distanced from the cross sectional boundary of the plug.

In further embodiments, the parallelogram, i.e., the configuration of the four sides of the recessed area of the plug may be a rectangle.

In a preferred embodiment, the plug is snap fit into the bore, and the plug is composed of a plastic material, namely “Delrin” acetal homopolymer.

In another preferred embodiment, the O-ring seal requires no cure time as the Epoxy solution does.

The backing plate may be composed of any metal, such as aluminum alloy or copper alloy.

The invention will now be further described in conjunction with the appended drawings of certain embodiments of the invention. These drawings are illustrative of certain invention embodiments and should not be construed as to limitations of the invention.

### BRIEF DESCRIPTION OF THE DRAWINGS

FIG. 1 is a perspective view of the back or water side of a target/backing plate assembly, showing the combination of RFID chip, chip housing plug, and backing plate bore into which the chip and plug are received;

FIG. 2 is a bottom plan view of the chip housing plug taken from open ended side of the plug that is adapted for positioning along the bottom of the backing plate bore;

FIG. 3 is a cross-sectional view of the plug taken along the lines and arrows 3-3 of FIG. 2; and

FIG. 4 is a plan view similar to that shown in FIG. 2 except that the chip is now shown snugly encapsulated within the recessed area of the plug.

### DETAILED DESCRIPTION

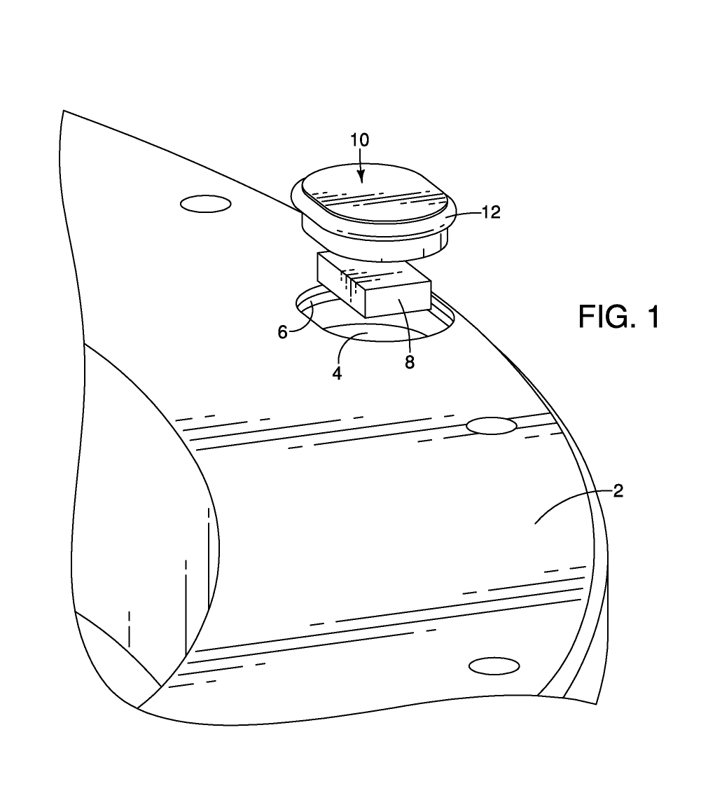

Turning to FIG. 1 of the drawings, there is shown the water side or back side of backing plate 2. It is to be noted that a sputter target (not shown) is placed along the side opposite from this back side of the backing plate 2 with a flange of the target overlying the outer periphery of the backing plate 2. The side of the backing plate 2 shown in FIG. 1 is commonly called the water side as a cooling water circuit or similar design impinges upon the backing plate here to remove heat from the overlying target during operation.

With further review of FIG. 1, a bore 4 is provided in this water side of the backing plate. The bore comprises a groove 6 formed around the bore. An RFID chip is shown as 8 in this figure and, as can be seen, is interposed between the chip housing (i.e., plug) 10 and bottom surface of the bore 4. An O-ring 12 is provided around the plug and is adapted for reception in groove 6 formed in the backing plate.

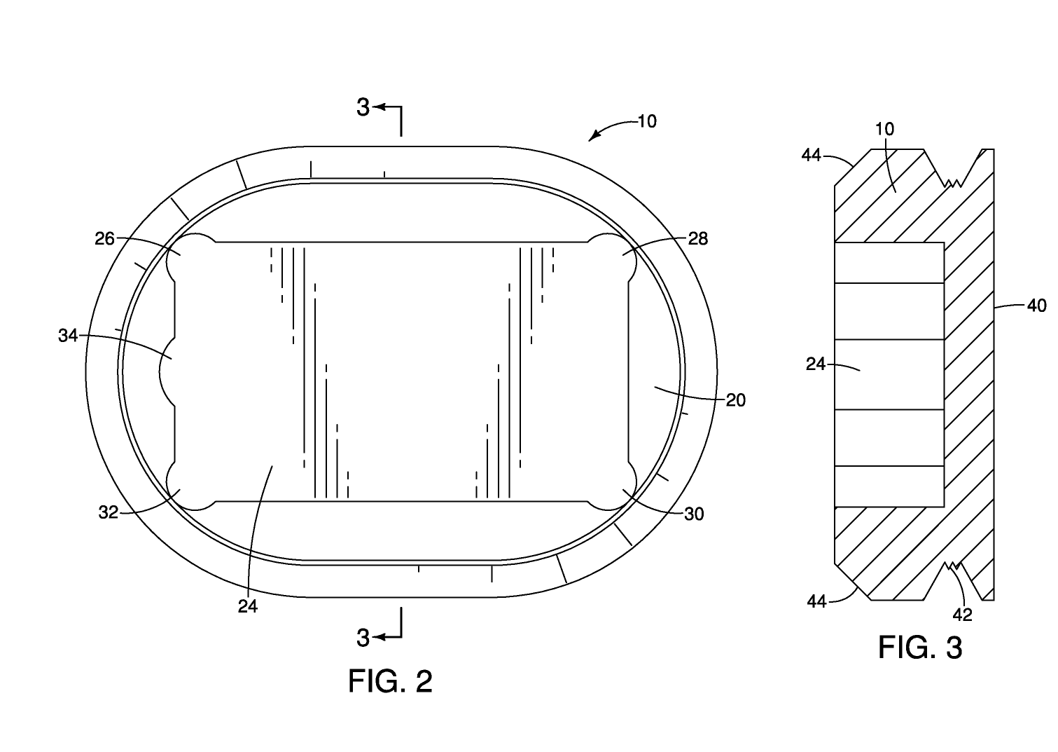

FIG. 2 illustrates further features of the plug 10. The plug comprises a solid section 20 which surrounds a recess 24. The recess is adapted for snug reception of the chip therein. As shown, the recess is shaped generally as a parallelogram with radiused corners 26, 28, 30, 32 provided at each of the intersecting sides of the parallelogram. Additionally, an installation concavity 34 is provided along one of the sides. This concavity 34 is adapted for reception of a small tool or the like to aid in placement and removal of the chip from the recess 24.

In the embodiment illustrated in FIG. 3, the outer face 40 of the plug is shown. This outer face 40 will provide a smooth, planar surface with the backside of the backing plate 2 when the plug is fully received within the bore 4. Groove 42 is provided in the upper portion of the plug proximate the outer face 40. This groove 42 will receive O-ring 12 shown in FIG. 1 and will mate with the groove 6 of the bore shown in FIG. 1 so as to provide a water tight seal, sealing the RFID chip from cooling water or the like which may impinge on backing plate 2 during operation or interruption of the sputtering process. Beveled edges 44 are formed along the bottom side of the plug 10 so as to provide for easy, friction or snap fitting of the plug 10 into the bore 4 of the backing plate. Thus, due to the friction or snap fit of the plug within the bore, welded or other extensive bonding techniques are not required to provide firm attachment of the plug within the bore.

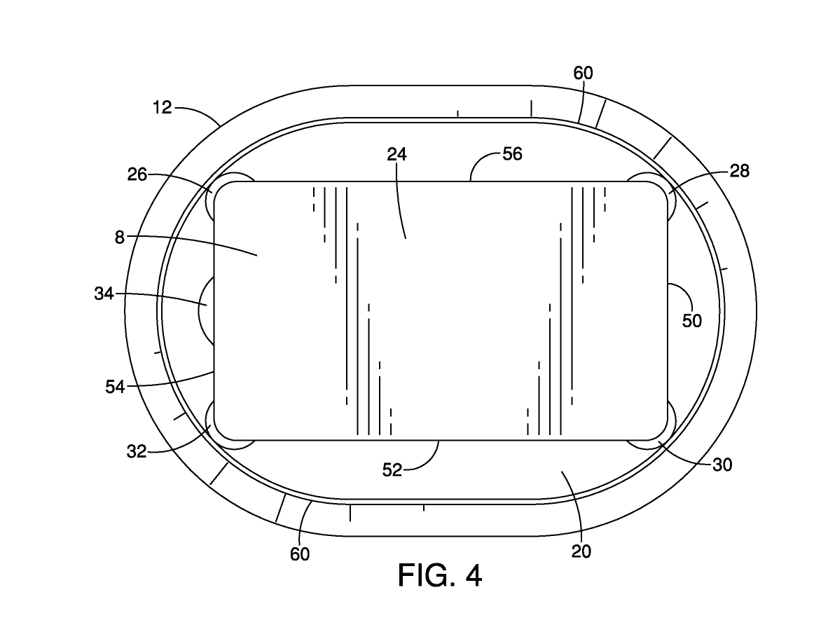

In FIG. 4, the RFID chip is shown snugly attached within recess 24. The solid section 20 of the plug surrounds the recess 24, and the boundary between the solid section and the recess is defined by linear surfaces 50, 52, 54, 56, and the aforementioned radiused corners 26, 28, 30, and 32. Note that in this embodiment of the invention, each of the side portions of the chip 8 are approximately equi-distant from the cross-sectional peripheral border of the plug shown as 60 in the drawing.

It is thus apparent in accordance with the above, that the invention maintains an optimized position within a sputtering target flange portion and underlining backing plate periphery that allows for maximum read and write range along with isolating the RFID tag from elements found in the sputtering process, especially liquids. The snap in fit is designed to allow for a person to firmly press with only their hands and snap the plug and associated chip into place. This engages an O-ring which seals the chip within the housing that is preferably made from “Delrin” polyacetal homopolymer. This keeps the chip optimally placed both horizontally and vertically in a precise, planned dimension.

As stated above, previously proposed designs utilized an epoxy to encapsulate the chip into the flange. The prior art designs could not guarantee an optimized distance from side walls nor could they guarantee an exact recipe for the epoxy. Due to the manual process required for preparation of the epoxy formulation, the epoxies often resulted in air bubble formation.

The present design utilizes “Delrin” to hold the commercially available identification tag. As a comparison, epoxy has a dielectric constant of 3.6 while Delrin has a constant 3.1. The higher dielectric constant, the more RF energy it reflects, and detunes the antenna.

The present design utilizes “Delrin” to hold the commercially available identification tag. As a comparison, epoxy has a cure time that is required before it is usable in the field while the Delrin assembly does not require any cure time. Typical cure times are 20 minutes to 24 hours. The elimination of cure times reduces the risk of staining the assembly during manufacturing, and reduces cycle time.

No other in-metal housings are known to us for use within sputtering targets. This housing is designed to allow for an optimal signal strength return to the interrogator and offers maximum read/write capabilities. Furthermore, all pre-fabricated designs commercially available do not take into account the requirement to isolate elements from manufacturing, especially water. The present design holds the chip at the exact distance required while preventing any water from entering the RFID chamber through utilization of an O-ring.

Sputtering target/backing plate assemblies with RFID chips in accordance with the invention result in pocket optimization. This requires an optimized two-way communication with the sputtering chamber for maximum read/write range without violating the original equipment manufacturer's design dictations. The present invention may be required to be implanted within metal surfaces in order to not compromise the design space of the original equipment manufacturer's requirements for proper functionality. The pocket surface must maintain the chip perpendicular to the transmission path of an external antenna, and also, the pocket must be tangent to the target outer diameter.

1. In a sputter target/backing plate assembly, an RFID tag containment combination comprising:
a bore formed in one of the backing plate or sputter target and a plug adapted for snug insertion into said bore;
said plug comprising an outer face, a recessed portion and a solid section, said solid section of said plug bordering at least a portion of said recessed portion;
said recessed portion configured to firmly receive said RFID tag therein.

2. Combination as recited in claim 1 wherein said bore is disposed along a peripheral portion of said backing plate.

3. Combination as recited in claim 2 wherein said outer face of said plug and said peripheral portion of said backing plate together define a planar surface.

4. Combination as recited in claim 3 further comprising an O-ring sealing said plug in said bore, wherein said plug comprises a peripheral groove, a second groove formed along a surface of said bore, said peripheral groove and said second groove providing a mating interfacial surface upon said snug insertion of said plug in said bore, said O-ring being seated along said interfacial surface.

5. Combination as recited in claim 4 wherein said plug recess comprises a tool installation concavity adapted for insertion of a tool therein to facilitate placement of said chip in said recess.

6. Combination as recited in claim 5 wherein said plug recess is defined by a parallelogram, each side of which is connected to another at a radiused section.

7. Combination as recited in claim 6 wherein each said side is equally distanced from the cross-sectional boundary of said plug.

8. Combination as recited in claim 7 wherein said parallelogram is a rectangle.

9. Combination as recited in claim 1 wherein said plug is snap fit into said bore.

10. Combination as recited in claim 9 wherein said plug is composed of plastic.

11. Combination as recited in claim 10 wherein said plastic is an acetal homopolymer.

12. Combination as recited in claim 9 wherein said backing plate is composed of metal.

13. Composition as recited in claim 12 wherein said metal is Al, Al alloy, Cu, Cu alloy, Ti, Ti alloy, Mo, Mo alloy Ta, Ta alloy, Ni, Ni alloy, Co, Co alloys.

14. Combination as recited in claim 13 wherein said Al alloy is Al 0.5 Cu.
